(19) United States
(12) Patent Application Publication
(10) Pub. No.: US 2024/0213198 A1
(43) Pub. Date: Jun. 27, 2024

(54) UNDER BUMP METALLIZATIONS, SOLDER COMPOSITIONS, AND STRUCTURES FOR DIE INTERCONNECTS ON INTEGRATED CIRCUIT PACKAGING

(71) Applicant: Intel Corporation, Santa Clara, CA (US)

(72) Inventors: Liang He, Chandler, AZ (US); Yue Deng, Chandler, AZ (US); Gang Duan, Chandler, AZ (US); Jung Kyu Han, Chandler, AZ (US); Ali Lehaf, Chandler, AZ (US); Srinivas Pietambaram, Chandler, AZ (US)

(73) Assignee: Intel Corporation, Santa Clara, CA (US)

(21) Appl. No.: 18/087,517

(22) Filed: Dec. 22, 2022

(51) Int. Cl. H01L 23/00; H01L 23/538

(52) U.S. Cl. CPC H01L 24/13; H01L 23/5381; H01L 23/5386; H01L 24/16; H01L 24/17; H01L 24/81; H01L 24/32; H01L 24/73; H01L 2224/13541; H01L 2224/1358; H01L 2224/13647; H01L 2224/13655; H01L 2224/13657; H01L 2224/1366; H01L 2224/13684; H01L 2224/16013; H01L 2224/16148; H01L 2224/16227; H01L 2224/16238; H01L 2224/16503; H01L 2224/1703; H01L 2224/32225; H01L 2224/73204; H01L 2224/81203; H01L 2224/8181; H01L 2224/81815; H01L 2924/3512; H01L 2924/381; H01L 2924/3841

(57) ABSTRACT

An electronic package comprises a first die having at least one first interconnect with solder over or under a first metal feature. A second die has at least one second interconnect to the first die, each second interconnect comprising a second metal feature comprising copper, solder over or under the second metal feature, and a layer between the solder and the second metal feature, wherein the layer comprises iron and has a different material than material of the first interconnect.

### BACKGROUND

Solder bump interconnect stacks can be used to couple one integrated circuit (IC) die to another IC die. The interconnect stacks typically comprise a copper pad, solder (or bump or ball), and under bump metallization (UBM) such as a diffusion barrier layer between the solder and the pad. Typically, the barrier layer, often formed of nickel when using a tin solder, reduces fast reaction kinetics and reduces interdiffusion of the copper in the pad with the tin solder. Without a barrier layer, the reaction of copper and solder leads to the fast formation of intermetallic compounds (IMCs). IMCs are generally more brittle, resulting in reduced mechanical integrity, and are less conductive, and therefore reduces performance of the IC package. Nickel barriers, however, are inadequate to slow IMC growth when the pitch between interconnects becomes too small and the thickness of the barrier material is reduced, thereby resulting in complete or substantial conversion of the solder into IMCs anyway.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a cross-sectional schematic diagram of an integrated circuit (IC) package according to at least one of the implementations disclosed herein;

FIG. 2A is a cross-sectional schematic diagram close-up of an interconnect on the package of FIG. 1 according to at least one of the implementations disclosed herein;

FIG. 2B is a cross-sectional schematic diagram close-up of a conventional interconnect;

FIG. 3 is another cross-sectional schematic diagram of the integrated circuit (IC) package of FIG. 1 according to at least one of the implementations disclosed herein;

FIG. 4A is a schematic diagram of a close-up of an alternative interconnect for the die assembly of FIG. 1 according to at least one of the implementations disclosed herein;

FIG. 4B is a schematic diagram of a conventional interconnect with solder wicking;

FIG. 4C is a schematic diagram of an interconnect with a solder wicking-reducing layer according to at least one of the implementations described herein;

FIG. 5A is a scanning electron microscopy image of a cross-sectional view of a close-up of a conventional interconnect with conventional solder

FIG. 5B is a scanning electron microscopy image of a cross-sectional view of a close-up of an interconnect using an alternative solder according to at least one of the implementations described herein;

FIG. 6 is a method of manufacturing an IC package according to at least one of the implementations disclosed herein;

FIGS. 7A-7M are IC package die assembly manufacturing stages according to at least one of the implementations disclosed herein;

FIG. 8 is a functional block diagram of an electronic computing device including an IC package with a die assembly in accordance with various implementations herein; and

FIG. 9 is a schematic diagram of a mobile computing platform and a data server machine employing an IC package with a die assembly in accordance with various implementations.

### DETAILED DESCRIPTION

Implementations discussed herein variously describe electronic packages with interconnect under bump metallizations (UBMs) that significantly reduce intermetallic compound (IMC) growth at bridge dice such as embedded multi-die interconnect bridges (EMIBs), chiplets, and other fine-pitch IC bridge structures, and in accordance with various implementations.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including integrated circuit architecture with interconnects that have barrier layers to slow intermetallic compound (IMC) growth.

Implementations are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

It also should be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that implementations may be practiced without these specific details. In some instances, well-known methods and devices are shown in block diagram form, rather than in detail, to avoid obscuring the implementations.

Reference throughout this specification to “an implementation” or “one implementation” or “some implementations” means that a particular feature, structure, function, or characteristic described in connection with the implementation is included in at least one implementation. Thus, the appearances of the phrase “in an implementation” or “in one implementation” or “some implementations” in various places throughout this specification are not necessarily referring to the same implementation. Furthermore, the particular features, structures, functions, or characteristics may be combined in any suitable manner in one or more implementations. For example, a first implementation may be combined with a second implementation anywhere the particular features, structures, functions, or characteristics associated with each of the two implementations are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular implementations, “connected” may be used to indicate that two or more elements are in direct physical, optical, and/or electrical contact with each other. “Coupled” may be used to indicate that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Herein, the term “conductive feature” or “metal feature” may refer to any metal structure within a package that is part of the extra-chip circuitry, and is generally embedded within the dielectric material of the package. Structures include traces, caps, contacts, and pads that are within a metallization layer or plane (e.g., in-plane). Vias or pillars that form interconnects interconnecting in-plane conductive features within adjacent metallization levels are included as well. “Conductive features” may be substituted by “metal features” or just “features” at times within the disclosure.

Herein, the term “circuit” or “module” may refer to one or more passive and/or active components that are arranged to cooperate with one another to provide a desired function. The term “signal” may refer to at least one current signal, voltage signal, magnetic signal, or data/clock signal.

The terms “substantially,” “close,” “approximately,” “near,” and “about,” generally refer to being within +/−10% of a target value (unless specifically specified). Unless otherwise specified the use of the ordinal adjectives “first.” “second,” and “third,” etc., to describe a common object, merely indicate that different instances of like objects are being referred to, and are not intended to imply that the objects so described must be in a given sequence, either temporally, spatially, in ranking, or in any other manner.

Also, chemical compounds without stoichiometry labels are not necessarily limited to 1:1 quantities. Thus, for example, “FeCo”, “FeNi”, “SnCuIn”, “NiWP” does not imply or limit the compound to a particular stoichiometry of those elements.

Under bump metallizations, solder compositions, and structures for die interconnects on integrated circuit packaging is described herein.

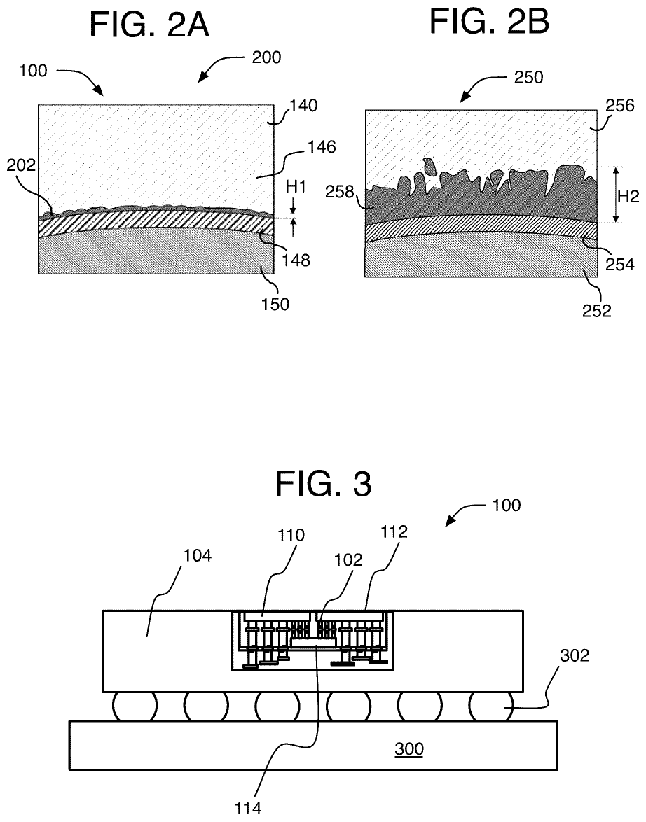

As mentioned, when interconnects at IC structures such as at bridge die structures have a fine pitch, such as 25 microns or less, a nickel diffusion barrier layer between the Sn solder and copper caps often needs to be very thin due to the reduction in pitch, such as with an Ni barrier layer with a thickness of 1-2 microns. At this small thickness, the nickel barrier and the solder still may be substantially or completely consumed and converted into Ni₃Sn₄ IMCs by fast reaction kinetics, especially during reflow and/or baking processes (see FIG. 2B discussed below for an example). This often results in reduced structural integrity of the interconnect as well as a lower Iₘₐₓ current or worse electromigration, and therefore, a reduction in performance of the IC package. Typically, for fine pitch interconnects, the thickness of solder needs to be reduced to be lower than the permissible height due to the reduction in the bump diameter. The thinner solder, however, raises the risk that all solder will be converted into IMCs with the growth rate of IMCs with an Ni barrier layer, even if the thickness of Ni is greater. Thus, an alternative UBM material that causes slower kinetics for IMC formation and growth with Sn solder is desired.

To resolve these issues, it has been found that a diffusion barrier layer formed of an iron composition or material on fine pitch interconnects reduces the formation of IMC at the interface between the solder and the barrier layer at the interconnects, and without significant increases in the barrier layer thickness. This reduction in the rate of IMC reaction kinetics and in turn IMC growth minimizes the consumption of the barrier layer, and in turn, the pad (or other metal feature in the interconnect to be coupled to the solder). Also, the slower reaction rate reduces the amount of solder that is converted into IMC material. As such, the electrical and mechanical properties of the interconnect are improved when a layer of iron is placed between solder and a metal feature such as a pillar, pad, or cap forming the interconnect.

In one form, the barrier layer may have an iron composition, iron alloy, or iron substance with another material or element. For example, the barrier layer may comprise iron and cobalt (FeCo) or iron and nickel (FeNi). The reaction kinetics for material such as FeCo or FeNi and solder are greatly reduced compared to that of the reaction between nickel and solder. Specifically, when the pads (or interconnects) have a fine pitch of 25 microns or smaller, and the iron alloy barrier layer has a thickness 2 microns or smaller, IMC with 1 micron or less, or approximately 0.5 microns or less, was found to occur due to solder consumption at high bake temperatures, and which was found to be ten times slower than the growth rate of the IMC with a nickel barrier layer. When bake temperature is low such that solder remains in a solid state, the growth rate of IMC on a FeCo barrier layer, for example, is three times slower than the growth rate of IMC on a Ni barrier layer. Thus, the higher temperature, the greater the benefit of the iron alloy barrier layer. Also, significant consumption, and in turn thickness reduction, of the iron alloy barrier layer itself was avoided, thereby preventing or reducing any substantial diffusion and reaction between the copper pad and the solder. Thus, the growth of the IMC, the consumption of the barrier layer, and consumption of the solder is reduced when a diffusion barrier layer that comprises iron is used between solder and metal features or caps on IC interconnects.

While at least some FeSn₂ IMC may be generated, this reduced IMC also may have additional constituents sourced from the solder and UBM. That is, the IMC may include more elemental constituents than just those in the barrier layer and the Sn from the solder, such as Cu from the pad in addition to elements from the UBM layer and solder. Additionally, the IMC growth may not be uniform. That is, the interface between the IMC and the solder may not be a straight plane, similar to the case when a material is plated over an underlying material.

Thus, by one form, one example implementation has an electronic package that comprises a first die (or in other words, at least one first die which may or may not be a monolithic die) having at least one first interconnect with solder over or under a first metal feature. A second die (or in other words, at least one second die which may or may not be a bridge die, EMIB, or chiplet) has at least one second interconnect to the first die, each second interconnect comprising a second metal feature comprising copper, solder over or under the second metal feature, and a layer between the solder and the second metal feature, wherein the layer comprises iron and has a different material than material of the first interconnect. By one form, the pitch of the first and second interconnects may be the same. Otherwise, the second interconnects may have a different pitch than the first interconnects. By one form, the pitch of the second interconnects is a smaller fine pitch than a larger pitch of the first interconnects.

Even when the barrier layer has iron, difficulties may still arise with solder wicking. Thermo-compression bonding (TCB) often includes holding one component on a hot pedestal often under vacuum, while a die is picked up by a bond head on an alignment and placement tool, and held securely and flat on the bond head also with vacuum. After the die is aligned with the opposite component (such as another die or package assembly) at its interconnect features, such as metal pillars, pads, or caps, the bond head comes down and stops when the die touches the opposite component. A constant force is then applied while the die is heated up quickly beyond the solidus temperature. As soon as the solder joint melts, the die is moved further down (solder chase) to ensure all solder joints are in contact. The die is held in position allowing the solder to reflow completely, and to wet the bump pads and copper pillars. While the solder is still in the molten state, the bond head retracts upwards controlling the solder joint height. The bond head then releases the vacuum holding the die and moves away as the solder joints have solidified.

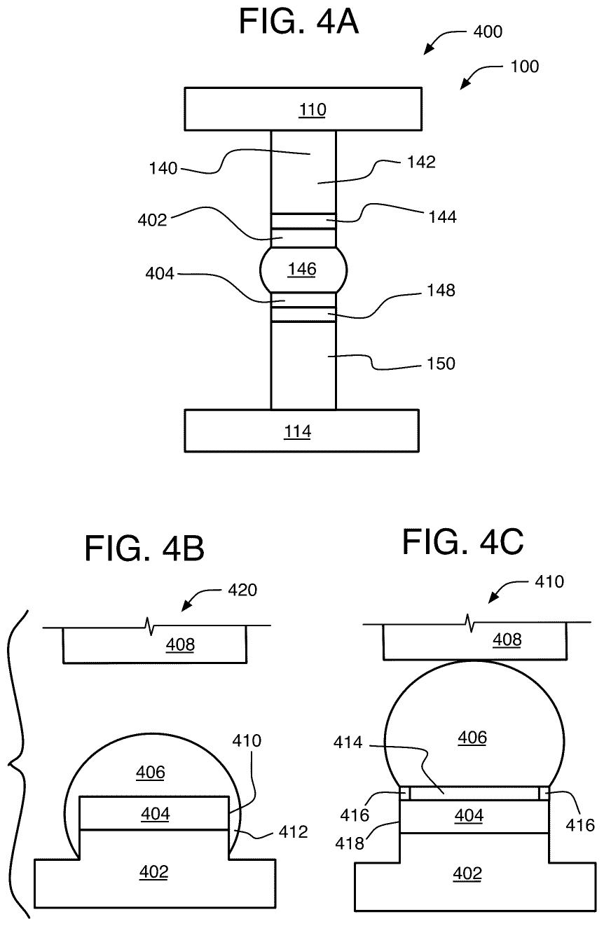

Weak or absent joints can occur, however, due to wicking of the solder away from the metal layer interfaces to be bonded and flow onto sidewalls of the barrier layer and underlying copper pad, often due to the temperature difference between the interconnect components as well as surface tension of molten solder. For reflow and (TCB) processes, the wicking also can result in full conversion of the Sn solder into IMC or may lead to non-uniform bump height that results in non-contact opens (NCO or missing bonds as shown by FIG. 4B described below)) and solder ball bridging (SBB) where solder from adjacent interconnects may touch and combine.

To resolve the wicking issues, adding a layer of Cu between the solder and the barrier layer has been found to quickly consume the molten solder near the bottom of a solder ball on the Cu layer. The fast consumption of the molten solder has a rate sufficient to stop or reduce wicking of solder down the sidewalls of the Cu layer and barrier layer underneath the Cu layer. IMC generated by conversion of the solder into IMC also assists to block the wicking of molten solder that has not been consumed. With this arrangement, more solder is maintained above the barrier layer rather than at the sidewalls, which in turn, provides a more reliable baking or reflow of solder that results in a high performance interconnect. Thus, this arrangement provides a barrier layer that slows IMC conversion while the Cu layer between the barrier layer and solder reduces the NCO and SBB risks through the reduction of wicking.

By yet another approach, the solder on the interconnect with the iron barrier layer may have a material to further reduce IMC and increase the mechanical integrity of the interconnect. Specifically, high current density electromigration (EM) such as that higher than 10⁴ A/cm² is often used on microelectronics. During high current density electromigration, metallic atoms are transported by electron flow which often results in undesired IMC polarity growth, which refers to the different flow directions of solder and UBM atoms and thus the accelerated IMC growth under the applied electron current, hillocks on the anode side, and cracks on the cathode side. These detrimental results at the interconnect joint reduce both the physical and electrical performance and reliability of the interconnect. To resolve these issues, a SnInCu solder may be used that was found to reduce EM thereby reducing the undesired IMC polarity growth, hillocks, and cracks, resulting in increased electrical and mechanical performance for an interconnect. By another alternative with the SnInCu solder, the barrier layer may be an NiWP layer instead of a layer with iron as described below.

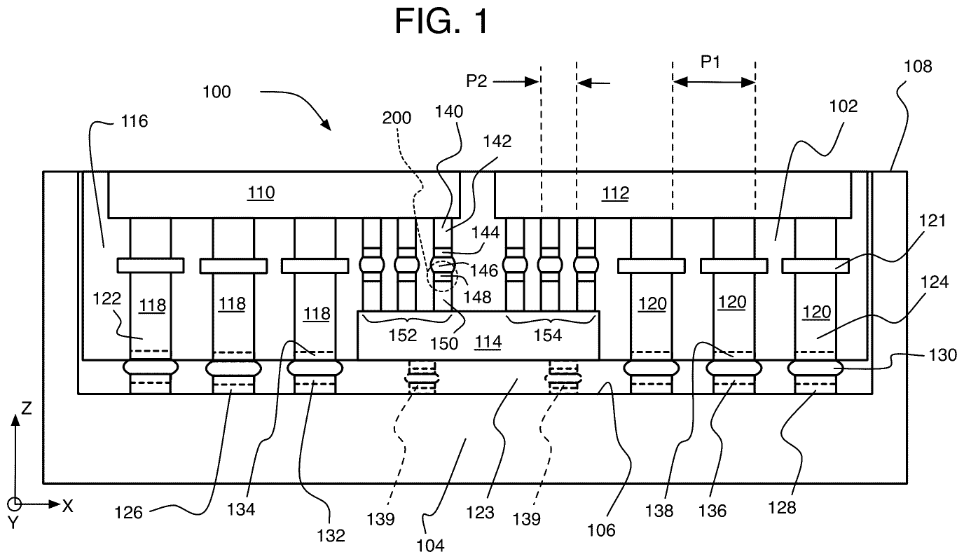

Referring now to FIG. 1 for one example arrangement, an IC package 100 has an IC package die assembly 102 on a base component 104 that is either a package substrate or host die that itself is mounted over a package substrate whether within, on, or under a stack of dice, and whether or not directly mounted on a substrate. The base component 104 otherwise may be any die, chip, device, semiconductor component, and so forth that can receive the die assembly 102. The base component 104 will be referred to herein as the substrate 104 for simplicity. The package substrate 104 may be an organic package substrate. That is, the package substrate 104 may comprise a plurality of laminated dielectric layers with conductive routing (not shown) embedded therein. The package substrate 104 also may comprise a core, a glass layer, or any other materials typical of electronic packaging architectures. Also, the substrate 104 may have a cavity 106 to receive the die assembly 102. Otherwise, the die assembly 102 itself may be a die or device that is mounted on a top surface 108 of the substrate 104.

In this example, the die assembly 102 may form a device with one or more functions and may be a heterogenous assembly. The die assembly 102 has chips or dice (referred to as first dice) including a left die 110 spaced laterally from a right die 112. By the example form herein, a bridge or second die 114 electrically and/or physically couples the left die 110 to the right 112. It will be understood that the term die refers to an integrated circuit (IC) component or chip, typically singulated from a wafer, that has one or more transistors and/or supporting circuitry to route electrical signals to the transistors, as well as any other IC components. It also will be understood, however, that this is one example arrangement and the die assembly 102 may have many different arrangements with more first dice (or other dice) 110 and 112 spaced laterally (X or Y direction according to the axes shown) or stacked vertically (in the Z direction), and more bridge or second dice 114. The first dice also need not always be on the same plane, level and/or layer of the die assembly. Thus, interconnects of the die may have different heights to one die than another.

While first dice 110 and 112 are shown above the second bridge die 114, the reverse may be used as well where the assembly 102 has the second die mounted above the first dice 110 and 112. Also, while the first dice 110 and 112 may be monolithic dice, and the second or bridge die 114 may be a chiplet as explained below, any or all three dice could be monolithic and/or chiplets. Also, the first dice 110 and 112 may be bridge dice as well. Many variations are contemplated.

By one form, each die 110 and 112 has its own array of first interconnects 118 and 120 respectively. The interconnects 118 and 120 may be via pillars, caps, or pads with one or more metal or conductive features for interconnection to another IC component such as a die, chip, device, board, or substrate 104, or such IC components in or on substrate 104. The interconnects 118 and 120 may have widened intermediate pads (or landings) 121 for coupling to traces, metallization layers, and so forth. While the interconnects are shown to be mainly cylindrical or polygonal, it will be understood that any of the interconnects herein may be another shape such as frusto-conical where the sidewalls of the interconnect tapers inward or outward from top to bottom of the interconnect.

The interconnects 118 and 120 of the dice 110 and 112 may be referred to as first, core, or non-bridge interconnects merely to distinguish from second or bridge interconnects 140 described below. The term core, as used herein, does not necessarily refer to an interconnect that provides coupling for a more primary function than that associated with the second interconnect 140, and the core interconnects may have no association with a type of die it couples to, whether a monolithic die, chiplet, die for core processors, and so forth. At a minimum, the second or bridge interconnects 140 couple a first to a second die and comprise an iron layer, while first or core interconnects are not limited to having iron layers and may not have a barrier layer at all between solder and a metal feature (whether a pillar, cap, pad, and so forth) of the first interconnect. The first interconnects 118 and 120 also may be first level interconnects (FLIs).

In addition to the arrangement or pattern of dice, the IC die assembly 102 may be formed of a dielectric, or one or more dielectric layers, 116, which may be a mold or mold layers, of mold resin, such as a polymer resin with insert fillers. The dielectric 116 may embed or cover the dice 110, 112, and 114, as well as one or more metallization layers that may include the interconnects 118, 120, and/or 140, or other interconnects. Thus, the metallization may include traces and vias, for example, and including interconnect vias. By other forms, the dielectric 116 may be inorganic dielectric material, such as, but not limited to, amorphous and polycrystalline silicon oxides, in some cases having a higher k than inter-layer dielectric (ILD) materials. In some other implementations, dielectric 116 comprises an organic material, such as, but not limited to, polymers, epoxy resins and epoxy resin composites, ceramics, and so forth. The metallization may be formed of copper and/or other conductive materials, or other metals.

In the example of package 100, the dice 110 and 112 may be directly coupled to the package substrate (or host die) 104 through their interconnects 118 and 120, and specifically by upper metal features 122 and 124 respectively and that may be die-side or upper pillar ends, caps, or pads. The metal features 122 and 124 couple to lower metal features 126 and 128 respectively that are substrate-side lower caps or pads on the substrate 104. The metal features 122 and 126 on interconnects 118 are coupled to each other by solder balls or bumps (or just solder) 130, while metal features 124 and 128 are coupled to each other on interconnects 120 by the solder 130. An optional layer 132, 134, 136, and/or 138 (shown by the dashed line), such as a barrier layer described below, may be positioned above or below the solder 130, or both, and between the solder 130 and one or more of the metal features 122, 124, 126, and/or 128. The metal features 122, 124, 126, and/or 128 may be formed of copper or other alloy or conductive material. Herein, the solder 130 and the metal features 122 and 126, and any lower layer 132 and/or upper layer 134, are considered to be part of interconnect 118. Thus, by one form, the interconnect 118 is considered to extend from die 110 to a surface of cavity 106 of substrate 104. The interconnects 120 are similar, and may be considered to extend from die 112, include metal feature 124, solder 130, metal feature 128, and any lower layer 136 and/or upper layer 138, and extend to the surface of the cavity 106 of the substrate 104. The solder 130 may comprise Sn or other solder material as mentioned below.

The cavity 106 between the IC die assembly 102 and substrate 104 may be filled with an underfill and/or adhesive filler with a material such as CUF (capillary underfill or MUF (mold underfill) material. Alternatively, the bridge or bridge die 114 also can be connected to the package substrate 104 through one or more interconnects 139 similar to interconnects 118 and 120, and in addition to bridge interconnects 140 described below. The alternative interconnects 139 may have pillars, caps, pads, and/or other interconnect components embedded within the die assembly 102 or may extend exteriorly of the assembly 102 as shown.

The bridge or bridge die 114 may electrically and physically couple the dice 110 and 112 to each other by the use of the bridge interconnects 140. The bridge die 114 may be an EMIB, chiplet, or other bridge IC structure. Particularly, the IC industry is continually striving to produce higher computational performance in smaller packages for use in various electronic products, such as computer servers, portable computers, electronic tablets, desktop computers, and mobile communication handsets. High performance computing products often now include one or more microelectronic packages that contain various combinations of semiconductor tiles, chips, chiplets, and dice that are integrated into one functional unit. These composite, or heterogeneous, IC device structures may include tiles, chips, chiplets, or dice created using diverse technologies and materials. The tiles, chips, chiplets, or dice may be stacked vertically, placed horizontally, or both. Connections between different devices may employ a variety of technologies, including direct bonding. Chiplets, rather than monolithic dice, disaggregate the circuits. Thus, the die assembly 102, or multiple die assemblies 102, may have multiple chiplets including multiple bridges where just one of the bridges is being shown here. The chiplet 114 may be communicatively coupled by interconnects (or bridge interconnects) 140 to other dice 110 and 112 thereby itself forming an interconnect bridge between the dice 110 and 112. Also as mentioned, dice 110 and 112 also can be chiplets. By one form, however, the dice 110 and 112 are monolithic IC dice.

The term “chiplet” is used herein to refer to a die that is part of IC die assembly 102 with dice 110 and 112, and here forming a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, by one example form, chiplet 114 is an individual die (or IC die) that can be connected together to other chiplets to create the functionalities of a monolithic IC. By using separate chiplets, each individual chiplet can be arranged and manufactured optimally for a particular functionality. In this case, dice 110 ad 112 could be chiplets as well. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall arrangement separated into different chiplets, each one optimized in terms of design and manufacturing, the overall yield and cost of the combined chiplet solution may be improved.

The connectivity between these chiplets (or a chiplet and monolithic IC dice) may be achievable by many different ways. For example, in 2.5D packaging solutions, a silicon interposer and through silicon vias (TSVs) connect dice at silicon interconnect speed in a minimal footprint. In another example as described herein, EMIBs have a silicon bridge or bridge die 114 embedded under the edges of two interconnecting dice 110 and 112 and facilitates electrical coupling between them. In a three-dimensional (3D) architecture, the chiplets are stacked one above the other, creating a smaller footprint overall, and could form one multi-layer bridge. Typically, the electrical connectivity and mechanical coupling in such 3D architecture is achieved using TSVs and fine pitch solder-based bumps (e.g., C2 interconnections could be used). The EMIB and the 3D stacked architecture also may be combined using an omni-directional interconnect (ODI), which allows for top-packaged chips to communicate with other chips horizontally using EMIB and vertically, using through mold vias (TMVs) which are typically larger than TSVs.

In some implementations that use chiplets, a composite chip may have a fill dielectric layer over back-end-of line (BEOL) metallization stack. A fill dielectric layer near the chiplet or bridge die here (in addition to the main or bulk dielectric of the die assembly 102, may fully surround chiplet sidewalls, embedding a chiplet within dielectric material, and may be the dielectric 116 or may be a separately molded dielectric abutting dielectric 116. A fill dielectric may stabilize and strengthen the composite die assembly 100, and/or provide a platform for higher BEOL metallization layers. In some implementations, a fill dielectric layer comprises an inorganic dielectric material, such as, but not limited to, amorphous and polycrystalline silicon oxides, in some cases having a higher k than inter-layer dielectric (ILD) materials. In some other implementations, a fill dielectric layer comprises an organic material, such as, but not limited to, epoxy resins and epoxy resin composites.

The bridge die 114 here, whether or not a chiplet, may communicatively couple the left first die 110 to the right first die 112 by using bridge interconnects (or bridge vias) 140. Herein, the bridge interconnects 140 may be considered to extend from the dice 110 or 112 to the bridge or second die 114, and each may include the components on that interconnect between the dice 110 or 112 on one end and bridge die 114 on the other end. In an implementation, the individual bridge interconnects 140 may include upper or die-side conductive or metal feature 142 that may be an upper or die-side pillar, cap, or pad. while a bridge-side lower metal feature 150 may be a lower bridge-side pillar, cap, or pad. The upper metal feature 142 is above solder 146 while the solder 146 is above the lower metal feature 150 so that the solder 146 is between the metal features 142 and 150 on the individual bridge interconnects 140. By one form, the solder 146 may be formed of Sn, or may comprise Sn, such as with SnCu, or may comprise a compound with In such as SnIn or SnInCu as discussed below, but otherwise may be any known solder that adequately forms connections on die assembly packages such as those described herein. The solder 130 on the first interconnects 118 and 120 may have the same material as interconnects 146 or may be a different material.

The bridge interconnect 140 also may have one or two layers 144 and 148, such as barrier layers, diffusion barrier layers, IMC barrier layers, or other types of layers, directly between the solder 146 and either or both of the metal features 142 and 150 so that each layer forms an interface with both the solder 146 and one of the metal features 142 or 148. This example shows two layers with the layer 144 positioned between the upper metal feature 142 and the solder 146, while the layer 148 is between the solder 146 and the lower metal feature 150. This arrangement with both layers 144 and 148 may be provided on each bridge interconnect 140. Alternatively, just one of the upper or lower layers 144 or 148 may be used on one or more individual interconnects 140 instead.

Thus, as mentioned, to accomplish the bridging structure, one group or array 152 of bridge interconnects 140 couples the bridge die 114 to the die 110 while another group or array 154 of bridge interconnects 140 couple the bridge die 114 to the other die 112. The arrays 152 and 154 may have a same or different number of interconnects, and may be many different same or different patterns as mentioned, or may have different pitches (both being at or less than 25 microns as described below), and may have different materials as long as at least one of the interconnects has an upper layer 144 or lower layer 148 or both that comprises iron.

The layer 144 or 148 may comprise a material that slows the reaction kinetics between the metal features and solder to minimize the conversion of the materials and growth of IMC. The layer 144 or 148 may comprise iron. By one form, the layer 144 or 148 comprises iron and another element or material such as cobalt or nickel (e.g., FeCo or FeNi). By one form, both layers 144 and 148 are used and have the same composition, and by other alternatives, may have a different composition. By one form, both layers 144 and 148 have iron and a different additional material (Co and Ni). Other additional materials could be used with Fe as well.

With a layer 144 or 148 comprising iron as described, the bridge interconnects 140 may have a pitch P2 that is smaller than the pitch P1 of the core (or non-bridge) interconnects 118 or 120. By one form, the bridge interconnect pitch P2 may be approximately 25 microns, or 25 microns or smaller. By one form, the core interconnect pitch P1 is larger than 25 microns, but in other options, the core interconnect pitch P2 can be the same as pitch P1, or any desired pitch. Also as mentioned, the pitches of arrays 152 and 154 may or may not be the same. Similarly, the pitches of interconnects 118 and 120 also may or may not be the same.

The layers 144 or 148 with iron also permit a reduced thickness of the layer 144 or 148. In an implementation, the layer 144 or 148 may have a thickness that is approximately 1 micron thick or greater. In an implementation, the layer 144 or 148 is 1-2 microns thick or 1 to less than 2 microns thick. Such a thickness may be used in any of the barrier layers mentioned herein.

It will be appreciated that the core or non-bridge interconnects may not have any barrier layers. In this case, the core interconnects 118 and 120 have a greater pitch and therefore can be wider, thus enabling thicker metal features and larger solder balls, so that all the material of the larger components should not be completely consumed and converted into IMC.

As mentioned, however, the core (or non-bridge) interconnects 118 and 120 also may have layers, including lower layers 132 and 136, and upper layers 134 and 138. By one form, these may be barrier layers without iron, such as a nickel barrier layer. Here again, since the core interconnects 118 and 120 can be wider, the barrier layer 132, 134, 136, and/or 138 can be thicker, such as equal to or greater than 2 microns thick, or in a range from 2 to 3 microns. With such an increase in thickness, the barrier layers 132, 134, 136, 138 should not be completely consumed and a sufficient thickness of the barrier layers 132, 134, 136, 138 should remain to sufficiently maintain the mechanical and physical integrity of the core interconnects 118 and 120.

It will be understood that among the upper and lower bridge interconnect layers 144 and 148, and the upper core (non-bridge) interconnect layers 134, 138 and lower core interconnect layers 132, 136, the die assembly 102 may have many arrangements of layers and layer materials as long as at least one of the bridge interconnect layers comprises iron. Thus, for example, when at least one of the bridge layers (upper or lower on the same interconnect) comprises iron, then at least one, or all, of the other bridge layer locations (upper and lower) and the upper and lower core layer locations: (1) may not have any layer, (2) may have a layer that does not have iron, (3) may have a nickel layer, (4) may have a layer with nickel and another material, (4) may have a layer with iron, (5) may have a layer with iron and another material, (6) may have a layer of FeCo, and/or (7) may have a layer with FeNi. By one approach, all of the same bridge interconnects have the same layer arrangement and all of the core interconnects have the same layer arrangement, but the material of all or at least one of the core interconnect layers is different than a material of all or at least one bridge interconnect layer.

Thus, by other alternative approaches, not all bridge interconnects 140 have the same number of layers 144 or 148. One or more bridge interconnects 140 may have no layers, while other bridge connects have one or two of the layers 144 or 148, or some bridge interconnects 140 may have one layer and other bridge interconnects have two layers. By one form, this could be arranged in a pattern, where for example, outer boundary interconnects have no layers or one layer), while interior bridge interconnects 140 have one layer or two layers, respectively, and vice-versa. Otherwise, it may be a different number of layers by rows or columns of bridge interconnects, just corners or centers of the array, and so forth. Also, the pattern may be limited to an array of bridge interconnects 140 that couple to the same first die 110 or 112. The pattern for each first die 110 and 112 may be the same or different.

Also, as with bridge interconnect layers 144 and 148, the same layer arrangements may be used on the core interconnects 118 and 120. Thus, all core interconnect layers 118 and 120 (or separate arrays of the interconnects 118 or 120) all may have the same number, zero, one, or two, layers. Otherwise, the core interconnects 118 and/or 120 may have varying number of layers on one assembly 100. Thus, while one or more interconnects have zero layers, others may have one layer or two layers. By some forms, while some interconnects 118 and 120 have one layer, others have two layers, and so forth. Thus, any desirable and/or efficient combination of zero, one, and two layer interconnects may be used. The layers may be used in different patterns of the interconnects 118 and 120 also as mentioned above with bridge interconnects 144 and 148.

To mention some specific alternatives, the layers on the bridge may have a different material than the material of the core interconnect layers 132, 134, 136, 138. Thus, while bridge interconnect layers 144 and 148 comprise iron, the core interconnect layers 132, 134, 136, 138 may not have iron, such as with nickel, or may have iron and a different additional material. Thus, when the bridge interconnect layers 144 or 148 or both have FeCo, then the core interconnect layers 132, 134, 136, and/or 138 may have FeNi, or vice-versa. Other iron alloy or iron substance or material may be used as well.

By another approach, regardless of the layer arrangements, the core interconnect layers 132, 134, 136, 138 may have a similar material as bridge interconnect layers 144 and 148 with a composition or material that minimizes growth of IMC on the interconnects. As with the bridge interconnects 140, the layers 132, 134, 136, and 138 may be either FeCo, FeNi, or a material or substance with iron and an additional material (or element).

Referring to FIGS. 2A-2B, with these layer arrangements, it can be shown that IMC is significantly reduced. Interconnect close up diagrams 200 (FIG. 2A) and 250 (FIG. 2B) are animated versions of real test results using Scanning Electron Microscopy (SEM) images of cross-sections of the disclosed FeCo layer UBM on FIG. 2A, and conventional solder bumping with Ni under bump metallization (or layer) (UBM) on FIG. 2B and, both after six reflows and while using the same magnification. The disclosed diagram 200 shows an interconnect similar to the bridge interconnect 140 with metal feature or Cu pillar 150 under barrier layer 148, which is under solder 146. The conventional setup 250 has a metal feature or Cu pillar 252, under the Ni layer 254, which is under an Sn solder 256.

As shown, the metal stack of the bridge interconnect 140 has a much thinner IMC and more UBM thickness retention for FeCo (layer 148) than Ni (layer 254) on the conventional diagram 250. The resulting FeSn₂ IMC 202 had a thickness H1 of approximately 1 μm or smaller, or approximately 0.5 μm or smaller, grown between the barrier layer 148 and the solder 146. The resulting thickness H1 of IMC 202 was much smaller than the thickness H2 of the Ni₃Sn₄ IMC 258, which was 3 microns and greater. Thus, the UBM with iron is sufficient as an alternative surface finish to reduce IMC growth kinetics and UBM consumption rate. While the initial conventional Ni layer 254 may be 2 microns thick or more for interconnects at a fine pitch region, the Ni layer 254 may be reduced to 1 micron thick or smaller, if still present at all, but after IMC growth.

Referring to FIG. 3, the electronic system or IC package 100 may have a board 300, such as a mother board, host board, and/or printed circuit board (PCB), and the package substrate 104, with the IC die assembly 102 mounted within the substrate 104, may be mounted on the board 300 by second level interconnects (SLIs) 302. While the SLIs 302 are shown as solder balls, it is to be appreciated that the SLIs 302 may be any suitable interconnect architecture, such as sockets or the like.

Referring to FIG. 4A-4C, one or more alternative interconnects 400 may be used on the package 100 and may include an additional layer of Cu between the barrier layer and the solder. This Cu layer may be a solder wick-reducing layer that reduces SBB and NCO during a bonding process. Interconnect 400 may include the dies 110 and 114, metal features 142 and 150, and barrier layers 144 and 148 as described above on die assembly 102. Interconnect 400 also may have at least one Cu layer, and here may include two Cu layers 402 and 404, where an additional Cu layer 402 may be between the barrier layer 144 and solder 146, or an additional Cu layer 404 may be between barrier layer 148 and solder 146, or both.

Referring to FIGS. 4B-4C, the difference in wicking flow with and without the extra Cu layer is explained with the interconnect joint setup 410 that has a single Cu layer shown, compared to a conventional interconnect joint setup 420. Both setups show a metal feature 402, a barrier layer 404 such as those described herein and may comprise iron, solder 406 that may comprise Sn or other material as described herein, and an opposite feature to by placed in contact and bonded to the solder 406. The opposite feature 408 could be any of those mentioned herein, whether metal feature, barrier layer, another Cu layer, and so forth. The opposite feature 408 may be shown during a stage of manufacturing and may not be in a final position. Significant here is the height of the opposite feature 408 at or above the solder 406, which is the same in both of the two setups 410 and 420.

Conventional setup 420 (FIG. 4B) shows that during a baking or reflow process, solder 406 may wick onto or wet the sidewalls 410 of the barrier layer and metal feature 402, which may leave a substantial amount of molten solder 412 at the sidewalls 410 rather than above the barrier layer 404. This results in a lowering of a height of a top of the solder ball 406 (lower bump height) which can cause NCO, while the molten solder 412 at the sidewalls 410 results in a widening of the solder 406 which may lead to SBB.

In comparison, setup 410 (FIG. 4C) shows that a Cu layer 414 between the solder 406 and barrier layer 404 can cause a fast reaction between the Sn in the solder and Cu resulting in fast consumption of solder. Thus, wicking or flowing solder is quickly consumed and converted into IMC 416 so that much less solder, if any, is present to wet sidewalls 418 of the barrier layer 404 or metal feature 402. Also, the IMC 416 may block at least some flow of the solder 406. Thus, with both the consumption and conversion of solder, this arrangement significantly reduces solder redeposition, and maintains desired and sufficient bump height (or bump reliability) to engage opposite features 408.

Reliability tests showed this benefit of adding a Cu layer between solder and an Ni barrier layer or UBM. Reduced solder redeposition resulted with no wicking fails. On the other hand, interconnect components with a Cu metal feature, then Ni barrier layer directly a solder in a metal stack showed a large amount of wicking and redeposition under the same conditions.

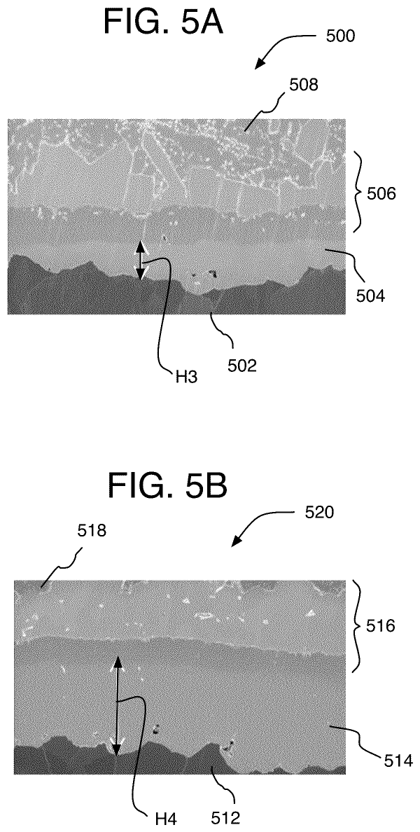

Referring to FIGS. 5A-5B, an alternative to Sn solder may include a solder composition to further reduce IMC polarity growth and other undesired results such as hillocks and cracks in the barrier layers and/other or metal features at an interconnect joint. These detrimental results may be reduced or eliminated to increase interconnect performance and integrity as mentioned above by using an alternative solder composition with higher maximum current capacity (Iₘₐₓ). When such a solder is used with the iron-comprising barrier layer as a surface finish (or barrier layer) for the metal feature facing the solder, the interconnect performance and integrity is very high.

Specifically, electromigration performance at solder joints may depend on IMC layer thickness, IMC growth kinetics, IMC formation, and so forth. A driving force for EM may be defined by the equation:

$${F}_{E M} = Z * e ρ J \qquad ( 1 )$$

where F_{EM} is the EM driving force, Z* is the effective charge number, e is the electron charge, ρ is the electrical resistivity, and J is the current density.

From a solder composition perspective, the effective charge of Sn is −18, and the effective charge of indium (In) is −2. Thus, while Sn moves along with electrons, indium moves against electron flow within the SnIn solder thereby slowing the electromigration, and in turn IMC generation. Specifically, a composition of SnIn or SnCuIn solder has been found to reduce EM, and in turn, reduce IMC polarity growth. When coupled with an iron NiFe, FeCo or even NiWP (nickel, tungsten, and phosphorous in any ratio) barrier layer (or UBM or surface treatment) between the solder and a metal feature such a pillar or pad, significant reductions in IMC formation and growth kinetics as well as a reduction in the barrier or UBM layer consumption rate occurs. This in turn provides a better barrier for EM.

Testing was performed for an NiWP barrier layer (or surface treatment) in an electromigration test similar to that of FIGS. 2A-2B. Here, a process of reference (POR) Ni barrier layer 504 in a SEM image 500 had a 65% reduction in thickness H3 as shown in FIG. 5A. The Ni barrier layer 504 is above a Cu metal feature 502 and below IMC 506 and solder 508. In FIG. 5B, an image 520 shows solder 518 over IMC 516, which is over a NiWP barrier layer 514, which is on a metal feature 512. A thickness H4 of the barrier layer 514 was merely reduced by 33%, which is about half the reduction of the Ni layer.

In other tests, it was demonstrated that Iₘₐₓ performance was significantly improved using SnInCu solder compared to SnCu solder composition. For example, mean time to failure (MTTF) data during electromigration/Iₘₐₓ testing under current loading resulted in interconnects with SnInCu solder composition having at least twice the lifetime than that of interconnects with SnCu solder.

Thus, it will be understood that by combining the barrier layers described herein with a SnInCu solder, the Iₘₐₓ performance at interconnects can be improved significantly. While the barrier layer that comprises iron is described herein, a barrier layer of NiWP on any one or more interconnects could be used with the SnInCu solder instead of a layer with iron or in addition to such a layer with iron.

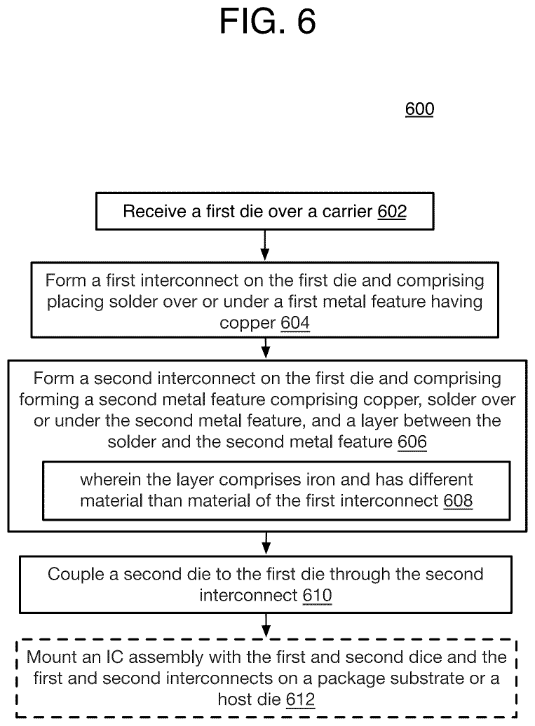

Referring to FIG. 6, an example process 600 of manufacturing an IC package is provided according to at least one of the implementations herein. Process 600 includes operations 602 to 612 generally numbered evenly, and electronic systems, devices, packages, and/or die assemblies 100, 200, and 502, 600, and 700 of FIGS. 1-3 and 5A-7 may be referred to herein where appropriate.

Process 600 may include “receive a first die over a carrier” 602, and this refers to at least one first die, and in one example two first dice, that have both non-bridge and bridge interconnects, and may be part of a die assembly to be flipped and mounted on a package substrate, host die, or other die or chip, although the die assembly could be mounted on a substrate without being flipped. This also indicates a die-first manufacturing process where the first dice are formed and positioned on the die assembly before mounting a bridge die over the first die or dice to couple the first dice to each other through the bridge die. The first dice may be mounted directly on a carrier or one or more dielectric layer, metallization layer, die, or chip between the first dice and the carrier and that may be part of the die assembly to be constructed with the first dice.

Process 600 may include “form a first interconnect on the first die and comprising placing solder over or under a first metal feature having copper” 604. This operation may involve forming the non-bridge or core interconnect. This may involve forming a first metal feature, whether a via pillar, cap, pad, and/or conductive feature, extending from either the first die or an opposite component to be coupled to the first die such as a package substrate, host die, or other die or chip. Depending on which of these structures is being used, solder then may be placed over or under the first metal feature. This may include placing the solder directly on the metal feature without an intervening layer, such as a barrier layer, or Cu layer to reduce solder wick, separating the solder from the metal feature. By other alternatives, the first interconnect may have such a layer or layers, as described herein, under, over, or on both sides of the solder. This may be performed by using lithography described below. The material forming the solder may be Sn, SnCu, or SnInCu as well as others as described above.

Process 600 may include “form a second interconnect on the first die and comprising forming a second metal feature comprising copper, solder over or under the second metal feature, and a layer between the solder and the second metal feature” 606. Here, this refers to the construction of the second or bridge interconnect and may proceed as mentioned with the first interconnect except here at least one of the layers is provided on, under, or over, the solder. By one example form then, one barrier layer may be deposited in direct contact with one of the metal features, optionally a Cu layer to reduce solder wicking may be placed on the barrier layer, and solder is then placed on or over the one or two layers. When two barrier layers are being formed on the second interconnect, the second barrier layer may be formed on an opposite component with another metal feature (and optionally another Cu layer) before being mounted on the solder to complete the interconnect

This operation 606 to form the second interconnect may include “wherein the layer comprises iron and has a different material than material of the first interconnect” 608. By one form, the layer may include an iron alloy, or iron plus another material. In a particular implementation, the layer comprises iron and cobalt (e.g., FeCo) or iron and nickel (e.g., FeNi). As noted above, the iron layer may be chosen in order to minimize the growth of IMC at the interface between the layer and the solder.

Also as mentioned, many different arrangements of materials or compositions may be used for the layers as long as at least one layer on the bridge interconnect comprises iron alloy. Thus, both the upper and lower layer on the same interconnect, whether a bridge or non-bridge interconnect, may be formed with the same material or a different material. Likewise, the material of one or both layers on the bridge interconnect may be formed with the same or different material than one or both layers on the non-bridge or core interconnect. Otherwise, the variations are as described above in detail. By one example, at least one of the second or bridge interconnects may have multiple layers with iron comprising at least one layer over the solder and at least one layer under the solder, wherein the layer over the solder has a different material than a material of the layer under the solder. By one form, both layers have iron plus an additional material that is different on each layer of the same interconnect, such as FeCo for one layer and FeNi for another layer. These same differences (FeCo versus FeNi) also applies from bridge interconnect layers to core interconnect layers.

It also will be noted that by a different approach, at least one barrier layer may be formed of NiWP instead of with iron and when SnInCu solder is being used, and at least one other layer may or may not have iron.

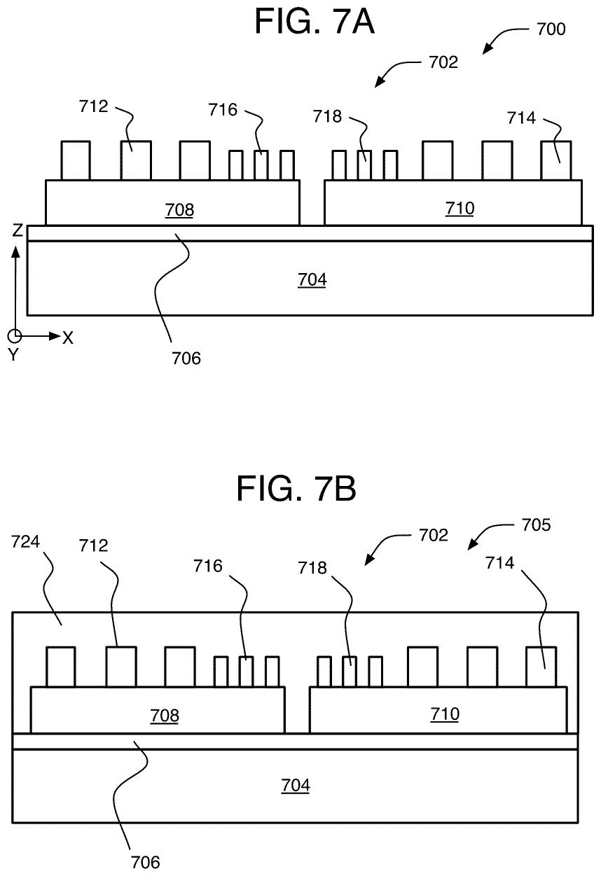

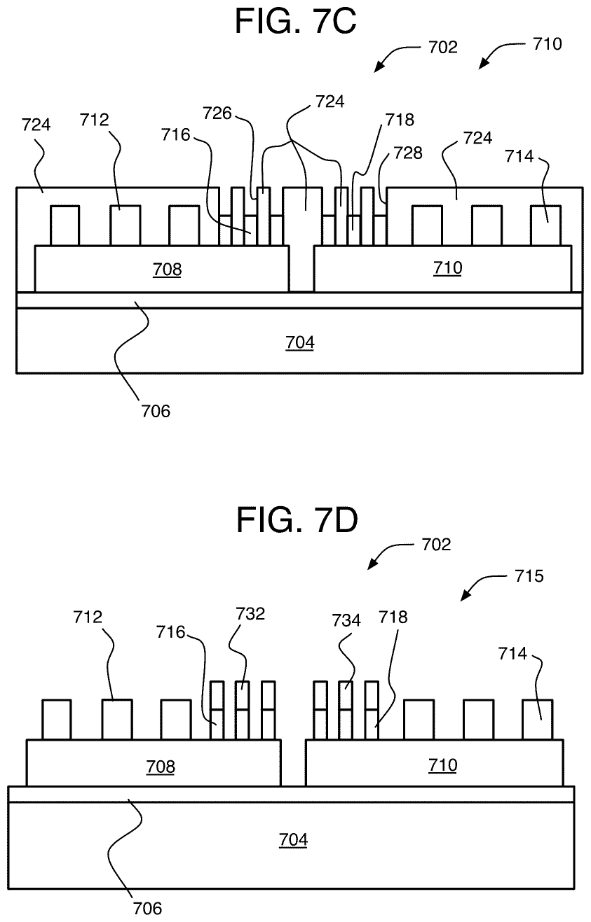

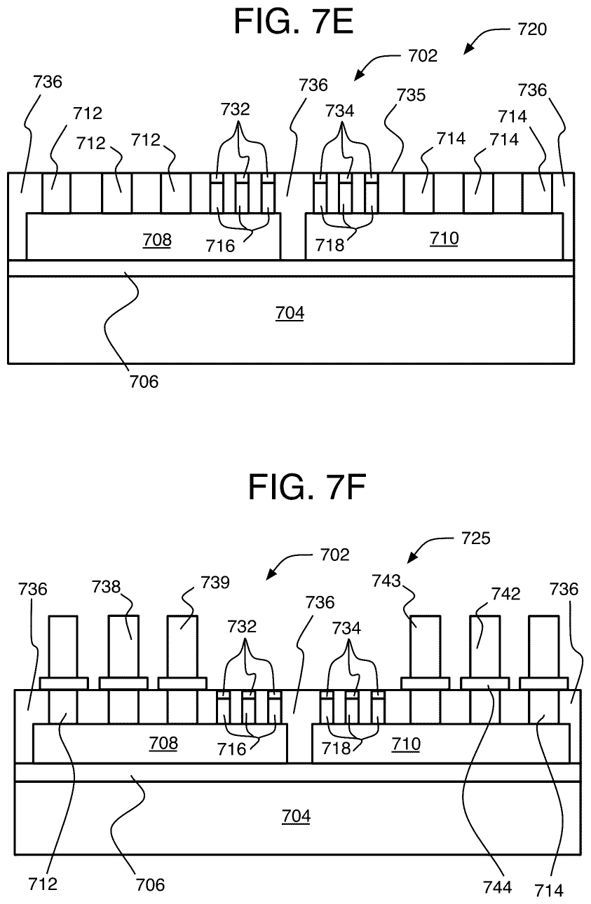

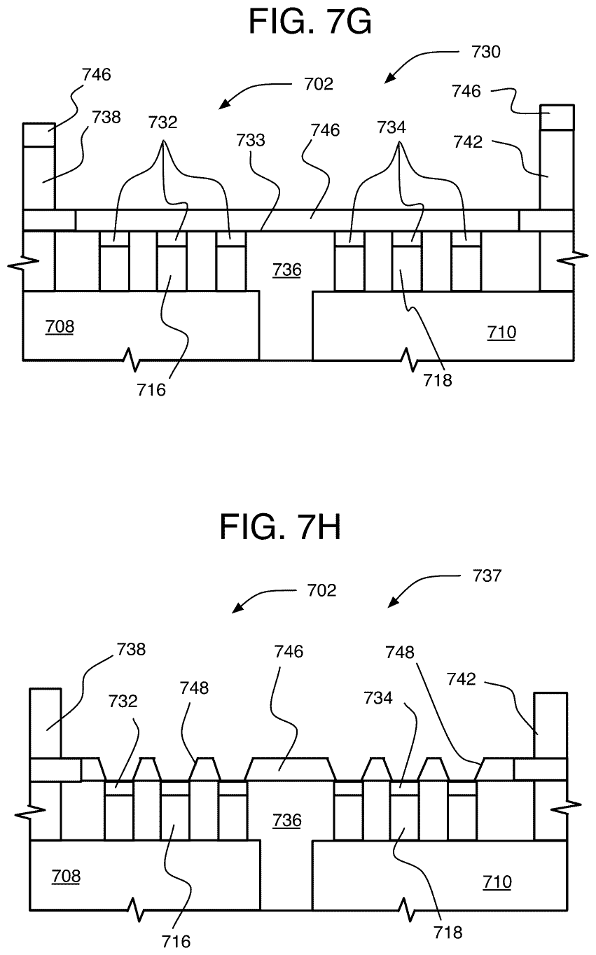

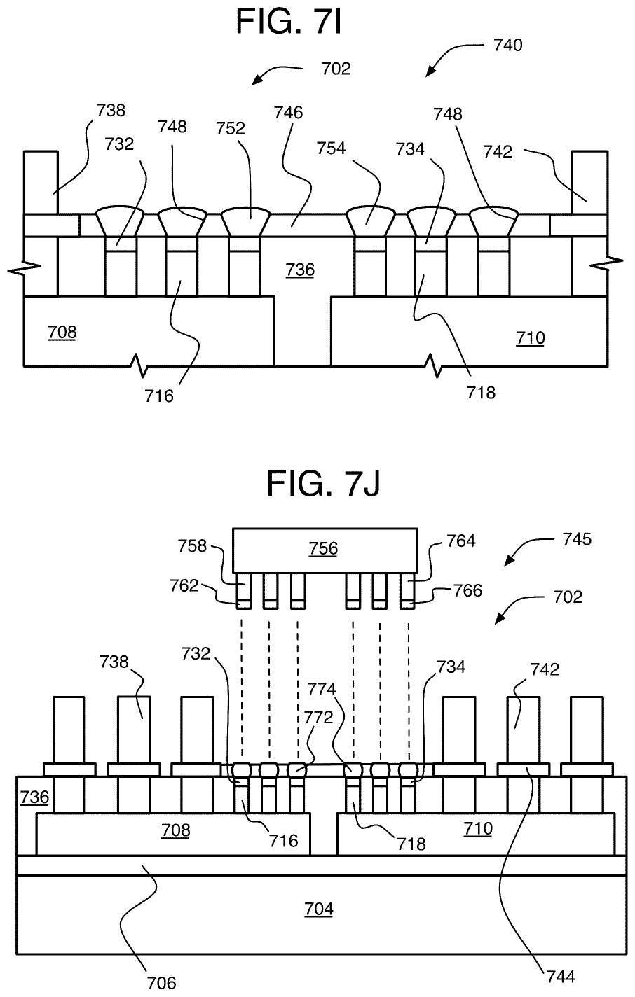

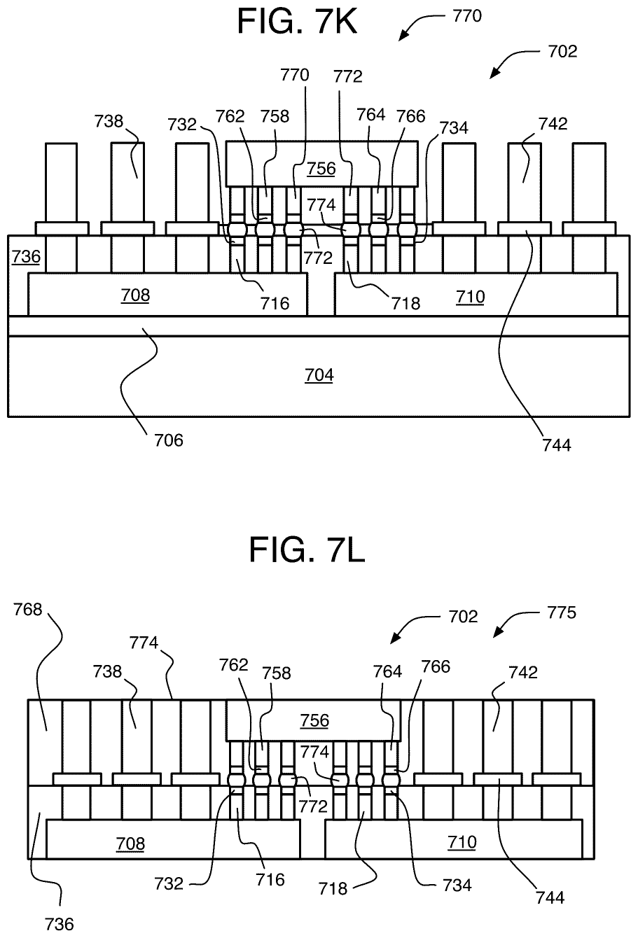

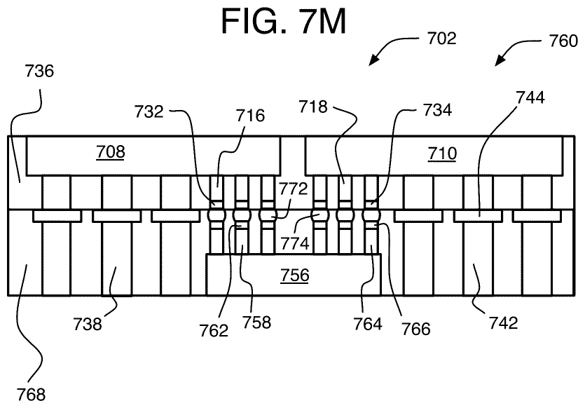

Process 600 may include “couple a second die to the first die through the second interconnect” 610. Completing the second interconnect comprises covering an intermediate assembly of the die with a lithography mask and photoresist layer, such as dry film resist (DFR) and including initially covering both incomplete first and second interconnects including first and second metal features such as pillars (or caps or pads) extending from the first die, and covering the assembly with the photoresist. Holes in the cured DFR and above the bridge pillars to be filled with layer material are formed at places covered by the mask. Thus, lithography may be used to construct the bridge interconnect barrier layers differently than the core interconnect layers. This process then may be repeated on the construction of the bridge die to form a layer on metal features extending from the bridge die. The second or bridge die then may be mounted to the die assembly by mounting the bridge interconnect metal feature or layers on the bridge die to the solder on the bridge interconnect barrier layers and/or die-side metal features. In an implementation, the second bridge die is mounted on the second interconnects of at least the two first dice (or a first die and a third die) to complete the bridge. The core interconnects can be completed subsequently and similarly. The details are described below with FIGS. 7A-7M.

Process 600 may include “mount an IC assembly with the first and second dice and the first and second interconnects on a package substrate or a host die” 612. Here, the die assembly can be completed, flipped if needed, and mounted on the other component, such as a substrate.

Referring to FIGS. 7A-7M for more detail, a process for assembling an IC package is shown, and particularly for assembling an IC package die assembly (or just die assembly) with interconnect layers comprising iron, in accordance with at last one of the implementations herein. The process stages numbered 700 to 760 by multiples of five are shown in FIGS. 7A-5M merely as one example process, and it will be appreciated that many different process flows may be used in order to provide such an interconnect layer as described herein.

The following manufacturing process shown by the stages 700 to 760 show a die first process to construct a die assembly where first dies are placed on a carrier first before mounting a second or bridge die over the first dies on the die assembly. The die assembly then may be flipped for mounting on a package substrate or other IC component such as a host die or other die or package component. Such a die first approach, rather than a die last approach provides more cost-effective solution than a die-last packaging approach.

Referring to FIG. 7A, an IC package die assembly intermediate manufacturing stage 700 shows a die assembly 702 with first dice 708 and 710 mounted on a carrier 704 with a separation or release film 706 between the carrier 704 and the dice 708 and 710. Die 708 has first or core interconnect metal features 712, where three are shown but more or less could be used (and this is true for any of the metal features on assembly 702), to couple to a package substrate or host device or die. The die 708 also has bridge interconnect metal features 716 to couple to a bridge die. Likewise, die 710 has core interconnect metal features 714 and bridge interconnect metal features 718. By one form, the bridge interconnects 716 and 718 may be formed near each other, without core interconnects interspersed among the bridge interconnects 716 and 718, so that the bridge interconnects 716 and 718 can couple to a bridge die

By one form, after or before singulation from a wafer, the die 708 and/or 710 may be tested so that only good dice (or known good dice (KGDs)) are used that have sufficient performance. Such die testing may include a burn-in thermal stress tests, high-voltage stress tests, reliability screening, bare die temporary package tests, wafer-level burn-in and test (WLBT), statistical post-processing test methods with reliability screening, and so forth.

The metal features or pillars 712, 714, 716, and 718 are shown here to be conductive metal pillars, but could be caps, pads, or other metallization features for transmitting electricity and/or signals between dice. The metal features may be formed of copper, copper alloy, or other conductive materials.

Also before or after singulation, the pillar metal features 712, 714, 716, and 718 may be formed by depositing a photoresist over the first dice 708 and 710, such as a laminated dry film resist (DFR), and a mask over the DFR. Portions of the mask are removed (or the mask is deposited in separate parts in spaced relation with gaps between the parts) to expose the DFR except where holes are to be formed in the DFR to place the pillars 712, 714, 716, and 718. UV light then may be used to cure or harden the DFR. The mask is removed, and chemical etching and/or laser are then used on the weaker (less cured) areas of the resist (previously under the mask) to form the holes. The pillars are then deposited or plated into the holes, and the hardened DFR is then stripped or removed to leave the pillars 712, 714, 716, and 718 in free standing states as shown on FIG. 7A. The bridge pillars 716 and 718 may be reduced in height relative to the core pillars 712 and 714 by grinding or by depositing the DFR with a smaller height in the second interconnect (516, 718) region for the bridge die. Otherwise, the bridge pillar can be deposited with lower height with application of shield during plating.

The pitch of the bridge metal features 716 and 718 may be 25 or less microns, while the pitch of the core metal features 712 and/or 714 may have the same pitch or a different pitch such as greater than 25 microns.

Referring to FIG. 7B, an IC package die assembly intermediate manufacturing stage 705 shows another photoresist 724 on the die assembly 702, which may be a laminated DFR (dry film resist). The locations on top of the bridge metal features on the DFR are blocked by a mask while the other area of the DFR is exposed to UV light, which leads to weaker and less cure in the area on top of the bridge metal features. These locations in the DFR are then removed by chemicals, leaving open holes on top of the bridge pillars 716 and 718.

Referring to FIG. 7C, an IC package die assembly intermediate manufacturing stage 710 shows that the etching forms recesses or holes (or openings) 726 and 728 in the resist 724 to receive the layer material to form the barrier layers above the tops of the individual bridge metal features 716 and 718.

In an implementation, the layers 732 and 734 may be deposited with a plating process or the like, and where an entire top surface of the bridge metal feature 716 or 718 is not exposed by the resist opening 726 or 728. This may occur when the sidewalls of the resist forming the recesses 726 or 728 are tapered and may extend over the top of the bridge metal features 716 or 718. In this case, the layer 732 or 734 may only cover the exposed portions of the bridge metal features 716 or 718 and not the entire top surface of the bridge metal feature 716 or 718. Additionally, the layer 732 or 734 may be conformal to the sidewalls of the resist opening 726 or 728. As such, sidewalls of the layer 732 or 734 may be tapered as well in some implementations. This is similar to the solder placement discussed below (FIGS. 7H-5J).

Referring to FIG. 7D, an IC package die assembly intermediate manufacturing stage 715 shows that the barrier layer material is then deposited or plated within the holes or recesses 726 or 728 and on the bridge metal features 716 and 718 to form layers 732 on die 708 and layers 734 on die 710. The resist 724 is then stripped or removed thereby removing any excess layer material on the resist 724.

In an implementation, the layers 732 and 734 may have a thickness that is approximately 1 micron thick or greater, or about 1-2 microns (or 1 to less than 2 microns). In an implementation, the layers 732 and 734 may comprise iron. In a particular implementation, the layers 732 and 734 comprises iron and cobalt (e.g., FeCo) or iron and nickel (e.g., FeNi). As noted above, the material of the layer 732 or 734 may be chosen in order to minimize the growth of IMC at the interface between the layer 732 and solder, and between layer 734 and solder (added in a subsequent processing operation). Also as mentioned above, by one form, the material of the layers 732 and 734 can vary as long as one of the layers on at least one of the individual bridge interconnects comprises iron, and as described in detail above. By yet another alternative mentioned herein, the layers 732 and 734 may comprise NiWP instead of an iron or iron alloy, and particularly if the solder is to comprise SnInCu as described herein.

Referring to FIG. 7E, an IC package die assembly intermediate manufacturing stage 720 shows deposited dielectric layer 736 such as a lamination layer or mold such as a mold resin deposited by compression molding. Such a mold or dielectric layer 736 may be a thermoset composite with polymer resin and about 80-90% insert fillers as primary components where the fillers may be reinforcement particles such as glass, carbon, and so forth. Otherwise the dielectric 736 can be organic polymer, and/or ceramics to name a few examples. A top of the dielectric layer 736 may be grinded and then chemical-mechanical polishing or planarization (CMP) may be applied so that the core metal features 712 and 714, and the bridge metal features 716 and 718, are exposed at a top surface of the dielectric layer 736.

It should be noted, however, that upper surfaces of the layers 732 and/or 734 may not always be maintained flush or coplanar with an outer surface (here an upper surface) 733 of the mold 736. Instead, upper ends of the layers 732 and/or 734 may be extended, before or after placement of mold 736, to form caps, pads, or other structure for the bridge interconnects. For example, the layers 732 and 734 may extend above the surface 733 of the mold 736 either by adding material to the layer 732 or 734, or by forming the mold surface 735 lower than an upper surface of the layers 732 and 734. The layers 732 and/or 734 also could be extended laterally to form a pad for example. Also, the metal features 716 and/or 718 could be extended laterally alone, or laterally and then downward or upward around layer 732 or 734 for example. Many variations exist.

In some implementations, dielectric 736 may be a single layer of dielectric (e.g., a dielectric laminate or a molded resin) and may have a thickness up to 800 microns. In some implementations, dielectric 736 will be part of a multilayer package stack comprising multiple dielectric layers, where only one portion of the package is shown in the figure so far. In some implementations, dielectric 736 may comprise multiple layers of an organic laminate or mold resin, each layer may have a thickness ranging between 10 to 100 or 10 to 200 microns. While dielectric layer boundaries may coincide with conductor levels embedded within the dielectric layer or between dielectric layers, multiple layers of dielectric may be between conductor planes.

Referring to FIG. 7F, an IC package die assembly intermediate manufacturing stage 725 shows the result of depositing or plating another metal feature section 739 and/or 743 to form core interconnects 738 and 742 respectively, here three are shown on each die 708 and 710, and by adding more metal material to metal features 712 and 714 to extend the heights of the pillars formed initially by metal features 712 and 714. This is accomplished by depositing a conductive material of metal feature sections 739 and 743, such as copper, coper alloy, or some other conductor by using lithography with masks and photoresists, which may be DFRs, as described above to form the metal features 712 and 714. Optionally, one or more widened intermediate pads (or landings) 744 may be formed with the lithography or other deposition or plating operation as well for coupling to traces, metallization layers, and so forth for metallization layers within or in between dielectric layers 736.

At this point in the process of FIGS. 7A-7M, the solder is placed directly on the layers 732 and 734 as follows. However, it will be appreciated that a Cu layer may be plated onto the layers 732 and 734 before depositing the solder instead to reduce solder wicking as described herein. This same stack order with an additional Cu layer may be used with any of the barrier layers whether on the first dies 708 and 710 and/or the second die 756 (FIG. 7J).

Referring to FIGS. 7G-71, IC die assembly manufacturing stages 730, 735, and 740 show a close up of the bridge metal features 716 and 718 to better explain formation of solder on the bridge metal features 716 and 718. Specifically, referring to FIG. 7G, an IC package die assembly intermediate manufacturing stage 730 discloses the depositing of a solder resist 746. The solder resist 746 may be a dielectric layer formed of insulating resin or other passivation layer, and may be laminated over a surface of the die assembly 702 to cover the barrier layers 732 and 734. When the layers or parts of metal features 716 and 718 extend upwardly here and outwardly from surface 733, the solder resist 746 may cover sidewalls and top surface of pads or caps formed by the layers 732 and/or 734, and/or metal features 716 and/or 718.

Referring to FIG. 7H, an IC package die assembly intermediate manufacturing stage 735 shows the intermediate die assembly 702 after solder resist openings 748 are formed into the solder resist 746 as shown. This may be performed with a patterning etch laser or other patterning process such as lithography. By one example, sidewalls of the openings 748 may be tapered in some implementations. Also, in some examples, the solder resist openings 748 may expose a portion of the top surface of the layers 732 and 734 such that the entire top surface of the layers 732 and 734 may not be exposed. However, in other implementations, the entire top surface of the layers 732 and 734 may be exposed.

Referring to FIG. 7I, an IC package die assembly intermediate manufacturing stage 740 shows the intermediate die assembly 702 after solder 752 and 754 is applied over the barrier layers 732 and 734 respectively. In an implementation, the solder 752 and 754 may comprise tin, SnCu, or SnInCu as explained herein. The solder may be applied through plating with laminated DFR or a microball process. The reflow or baking operations typically involve melting the solder above its melting temperature to form the joint between the solder and the diffusion barrier layer and form the spherical shape of the solder bumps. As a result, a reduced height or growth IMC may develop at the interface between the barrier layer 732 or 734 and the solder 752 and 754, respectively. The IMC may be substantially similar to the IMC 202 described in greater detail above with respect to FIG. 2A. That is, an IMC with a thickness of approximately 1 μm or smaller, or approximately 0.5 μm or smaller may be provided between the barrier layer 732 or 734 and the solder 752 or 754 respectively. It is to be appreciated that the thickness of the IMC is largely dependent on the thermal cycles the package experiences. However, it also is to be appreciated that for a given set of thermal cycles, the IMC thickness of an iron and cobalt barrier layer or an iron and nickel barrier layer, for example, will be smaller than the IMC thickness of a nickel barrier layer (or interconnect with no barrier layer). In an implementation, the IMC may comprise iron and tin, though other constituents may also be present in the IMC, depending on the composition of the barrier layer 332, 334 and the solder 752, 754.

Referring to FIG. 7J, an IC package die assembly intermediate manufacturing stage 745 shows the intermediate die assembly 702, and shows a mounting action to communicatively couple, and mount, a second or bridge die 756 to the first dice 708 and 710. The bridge die 756 may be an EMIB, chiplet, or other bridge structure circuitry. In this example, and to provide the bridge-side bridge interconnect structure, the bridge die 756 may have bridge-side metal features 758 and 764 that may be pillars, caps, pads, and so forth formed of copper, copper alloy or other conductive metal. Each or individual bridge-side metal feature 758 may have an end connected to, or coupled with, a layer 762, such as a barrier layer described herein, while bridge-side metal features 764 may be connected to, or coupled with, layers 766 that may be barrier layers. The layers 762 and 766 may be formed of the same or different material as the layers 732 and 734.

The bridge die 756 may be formed on a wafer with the bridge-side interconnect structures, then singulated, and lifted, aligned, and placed on the die assembly 702 by alignment tools such as thermocompression bonding tools. When the second or bridge die 756 is mounted onto the first dice 708 and 710, and in turn onto the die assembly 702, a group or array of the bridge-side or bridge metal features 758 is coupled to the die metal features 716 by engaging the bridge layers 762 to the solder 752 that may be already formed on or over the die layers 732. Likewise, a group or array of the bridge-side or bridge metal features 764 is coupled to the die metal features 718 by engaging the bridge layers 766 to the solder 754 that may be already formed on or over the die layers 734. Once positioned, the die assembly may be baked or reflowed as many times as desired to sufficiently physically connect the bridge layers 762 and 766 to the solder 752 and 754 respectively. IMC may be formed for the interface between the solder 752 or 754 and the bridge layers 762 and 766 respectively, and as described with the interface between the solder 752 and 754 and the die layers 732 and 734. This structure establishes the full bridge interconnect height from bridge die 756 to first dice 708 and 710 as described below on FIG. 7K.

It will be appreciated that the same operations to form the die-side structure of the bridge interconnects, such as lithography, also may be applied to form the bridge-side structure of the bridge interconnects just explained. It also will be appreciated by one alternative, dielectric mold alone, or with solder, may be formed on the bridge die rather than the die assembly or first die side, at least at a region of the bridge interconnects. It also will be appreciated that other variations may be used, such as the use of a single layer (upper or lower) on a solder of a bridge interconnect, or two layers on opposite side of the solder on the same bridge interconnect that do not have the same material.

Referring to FIG. 7K, an IC package die assembly intermediate manufacturing stage 750 shows the intermediate die assembly 702 with the bridge or second die 756 mounted on the first dice 708 and 710, and the completion of the bridge interconnects 770 and 772. The bridge interconnect 770 and 772 include, respectively, at least the die-side metal features 716 and 718, the die-side barrier layers 732 and 734, the solder 752, opposite bridge-side barrier layers 762 and 766, and the bridge-side metal features 758 and 764. At this stage, the bridge interconnects 770 and 772 may have sufficient strength to hold the bridge die up at least until mold is placed around the bridge die to strengthen the support.

Referring to FIG. 7L, an IC package die assembly intermediate manufacturing stage 755 shows the intermediate die assembly 702 where a dielectric layer 768 is deposited and that may have the same or similar materials as dielectric or mold 736. Grinding and CMP also may be performed on an upper surface 774 of the mold 768.

Referring to FIG. 7M, an IC package die assembly intermediate manufacturing stage 760 shows the intermediate die assembly 702 flipped and ready for mounting on a package substrate such as substrate 104 as shown on FIG. 1. This may be performed by using FLI solder balls or bumps on the package substrate to connect to, or become part of, core interconnects 738 and 742, whether within a cavity formed on the substrate to receive the die assembly 702 (or 102) or to be mounted on an upper surface of the substrate. Also as mentioned, instead of a substrate, the die assembly may be mounted on a host die or other package component. Also, the die assembly need not always be flipped, and may be mounted to the substrate with the bridge above the first dice.

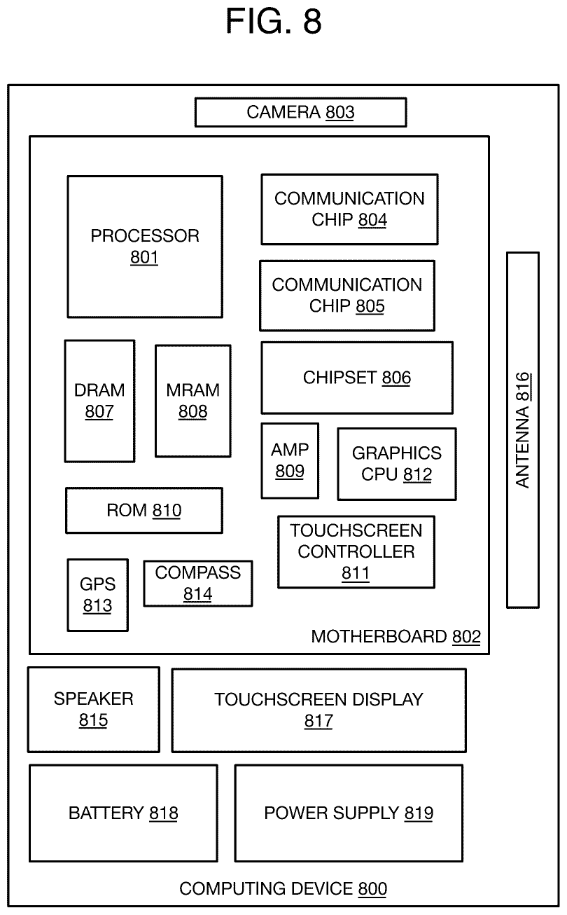

Referring to FIG. 8, an electronic computing device 800 in accordance with art least one implementation herein of the disclosed devices may have a package substrate or mother board 802 with a number of components, including but not limited to a processor (e.g., an applications processor) 801. The processor 801 may be physically and/or electrically coupled to the package substrate or board 802. In some implementations, processor 801 is within a composite IC chip structure, and the processor 81 may include first circuitry with first dice coupled to each other through a bridge die such as an EMIB or chiplet as described herein, for example. Processor 801 may be implemented with circuitry in either or both of the host IC chips and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 804 and 805 also may be physically and/or electrically coupled to the package substrate or board 802. In further implementations, communication chips 804 and 805 may be part of processor 801. Depending on its applications, computing device 800 may include other components that may or may not be physically and electrically coupled to package substrate or board 802. These other components include, but are not limited to, volatile memory (e.g., DRAM 807), non-volatile memory (e.g., ROM 810), flash memory (e.g., NAND or NOR), magnetic memory (MRAM 808), a graphics processor (CPU) 812, a digital signal processor, a crypto processor, a chipset 806, an antenna 816, touchscreen display 817, touchscreen controller 811, battery unit 818, audio codec, video codec, power amplifier 809, global positioning system (GPS) device 813, compass 814, accelerometer, gyroscope, speaker 815, camera 803, and mass storage device (such as hard disk drive, solid-state drive (SSD), compact disk (CD), digital versatile disk (DVD), and so forth), and a power supply unit 819, or the like. In some exemplary implementations, any of the IC structures, architecture, or units on device 800 or described in any of the units mentioned above, may have the interconnect structure described above. Thus, for example, in addition to being formed by circuitry of processor 801, or a composite IC chip of processor 801, the first circuitry or first dice bridged by a second die or chiplet as described herein, also or instead may be implemented by an electronic memory (e.g., MRAM 808 or DRAM 807).

The communication chips 804 and 805 may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some implementations the devices might not. The communication chip 804 may implement any of a number of short-range wireless standards or protocols, including but not limited to Wi-Fi (IEEE 802.11 family), Bluetooth, and others, and communications chip 805 may implement longer-range wireless standards or protocols such as WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, derivatives thereof, as well as any other wireless protocols that are designated as 3G, 4G, 5G, and beyond.

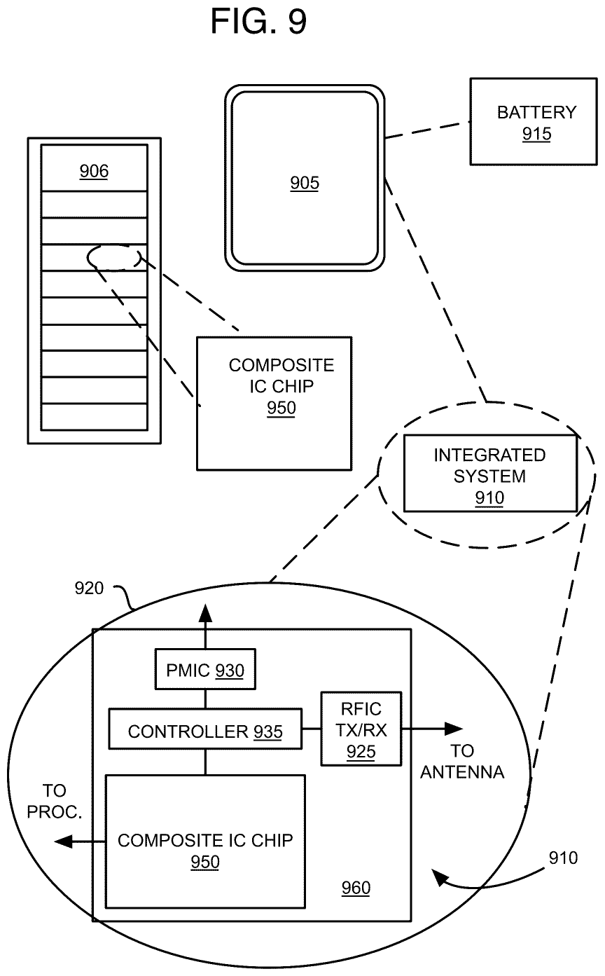

Referring to FIG. 9, a mobile computing platform 905 and a data server machine 906 employing an IC device included on a package substrate 960 as described elsewhere herein. Computing device 600 may be found inside platform 905 or server machine 906, for example. The server machine 906 may be any commercial server, for example including any number of high-performance computing platforms disposed within a rack and networked together for electronic data processing, which in the exemplary implementation includes structure of at least one IC die assembly on substrate 960 and used to connect bridge die, for example as described elsewhere herein, and may include a chiplet bonded to multiple die over a host IC chip and/or the package substrate 960. The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), a chip-level or package-level integrated system 910, and a battery 915.

Whether disposed within the integrated system 910 illustrated in the expanded view 920, or as a stand-alone package within the server machine 906, composite IC chip 950 may include a bridge die or chiplet bonded to multiple dice, for example as described elsewhere herein. Composite IC chip 950 may be further coupled to or over package substrate 960 and may comprise one or more of a power management integrated circuit (PMIC) 930, RF (wireless) integrated circuit (RFIC) 925 including a wideband RF (wireless) transmitter and/or receiver (TX/RX) (e.g., including a digital baseband and an analog front end module further comprises a power amplifier on a transmit path and a low noise amplifier on a receive path), and a controller 935. PMIC 930 may perform battery power regulation, DC-to-DC conversion, etc., and so has an input coupled to battery 915 and with an output providing a current supply to other functional modules. As further illustrated, in the exemplary implementation, RFIC 925 may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDcPA+, HSUPA+, EDGE, GSM, GPRS, CDMA, TDMA, DECT, Bluetooth, derivatives thereof, as well as any other wireless protocols that are designated as 3G, 4G, 4G, and beyond. Any of these IC units or components over the substrate may include the bridge die, chiplet, and/or EMIB with one or more interconnects to other die as described herein.

It is understood that the subject matter of the present description is not necessarily limited to specific applications illustrated in FIGS. 1-9. The subject matter may be applied to other electronic, microelectronic, or integrated circuit (IC) devices and assembly applications, as well as any appropriate electronic application, as will be understood to those skilled in the art.

The following examples pertain to further implementations. Specifics in the examples may be used anywhere in one or more implementations.

Example 1: an electronic package, comprises a first die having at least one first interconnect with solder over or under a first metal feature; and a second die having at least one second interconnect to the first die, each second interconnect comprising a second metal feature comprising copper, solder over or under the second metal feature, and a layer between the solder and the second metal feature, wherein the layer comprises iron and has a different material than material of the first interconnect.

Example 2: the subject matter of example 1, wherein the layer further comprises cobalt.

Example 3: the subject matter of example 1, wherein the layer further comprises nickel.

Example 4: the subject matter of any one of examples 1 to 3, wherein the first interconnect is without an intermetallic compound (IMC) barrier layer between the solder and metal features on the first interconnect.

Example 5: the subject matter of any one of examples 1 to 3, wherein the first interconnect comprises a first layer between the solder and first metal feature, wherein the layer of the second interconnect is a second layer, and wherein the first layer is without iron.

Example 6: the subject matter of example 5, wherein the first layer comprises nickel and is a barrier layer.

Example 7: the subject matter of example 1, wherein the first interconnect comprises a first layer between the solder and first metal feature, wherein the layer of the second interconnect is a second layer, and wherein the first layer comprises iron and a first material and the second layer comprises iron and a second material different than the first material.

Example 8: the subject matter of example 7, wherein the first layer comprises iron and nickel and the second layer comprises iron and cobalt.

Example 9: the subject matter of example 7, wherein the first layer

comprises iron and cobalt and the second layer comprises iron and nickel.

Example 10: the subject matter of any one of examples 1 to 9, wherein the electronic package comprises multiple first interconnects and multiple second interconnects, and wherein the multiple first interconnects have a pitch greater than a pitch of the multiple second interconnects.

Example 11: the subject matter of any one of examples 1 to 10, wherein a thickness of the layer is approximately 1 micron or thicker.

Example 12: the subject matter of any one of examples 1 to 11, wherein the second die comprises an interconnect to a third die, wherein the second die is at least one of a bridge die, an embedded multi-die interconnect bridge (EMIB), or a chiplet, and wherein the second die couples the first die to the third die.

Example 13: a method of manufacturing an electronic package comprises receiving a first die over a carrier; forming a first interconnect on the first die and comprising placing solder over or under a first metal feature having copper; forming a second interconnect on the first die and comprising forming a second metal feature comprising copper, solder over or under the second metal feature, and a layer between the solder and the second metal feature, wherein the layer comprises iron and has a different material than material of the first interconnect; and coupling a second die to the first die through the second interconnect.

Example 14: the subject matter of example 13, wherein the method comprises coupling the second die to a third die over the carrier and having the first and second interconnects, and coupling through a second interconnect of the third die.

Example 15: the subject matter of example 13 or 14, wherein the method comprises forming multiple first interconnects on the first die with a pitch greater than 25 microns and multiple second interconnects on the first die with a pitch equal to or less than 25 microns.

Example 16: the subject matter of any one of examples 13 to 15, wherein forming the second interconnect comprises covering an intermediate assembly with the first and second metal features with a resist; exposing the second metal features through openings in the resist without exposing the first metal features; and placing the layer on the second metal features within the openings.

Example 17: the subject matter of any one of examples 13 to 16, wherein forming the layer comprises further forming the layer with at least one of cobalt or nickel.

Example 18: the subject matter of any one of examples 13 to 17, wherein the layer is a second layer, the method comprising placing a first layer between solder and the first metal feature on the first interconnect, and comprising forming the first layer of a material different than a material of the second layer.

Example 19: the subject matter of any one of examples 13 to 18, wherein the first layer comprises a material that comprises iron and another material different than a material of the second layer.

Example 20: the subject matter of any one of examples 13 to 19, wherein the first layer comprises nickel, iron and nickel, or iron and cobalt.

Example 21: an electronic system, comprises multiple first dice; at least one first interconnect on each first die and comprising solder over or under a first metal feature; at least one second interconnect on each first die and comprising a second metal feature, solder over or under the second metal feature, and a layer between the solder and the second metal feature, wherein the layer comprises iron and has a different material than material of the first interconnect; and a second die coupled to the second interconnects of multiple first dice.

Example 22: the subject matter of example 21, wherein at least one of the first reconnects or at least one of the second interconnects or both has multiple layers comprising at least one layer over the solder and at least one layer under the solder, wherein the layer over the solder has a different material than a material of the layer under the solder.

Example 23: the subject matter of example 22, wherein both layers above and below the solder on a same interconnect comprises iron, and wherein the layer under the solder comprises a first additional material different than a second additional material of the layer over the solder.

Example 24: the subject matter of any one of examples 21 to 23, wherein the layer is a barrier layer, and the system comprises a Cu layer between the barrier layer and the solder.

Example 25: the subject matter of any one of examples 21 to 24, wherein the solder comprises SnInCu.

Example 26: The electronic system of example 21 further comprising an intermetallic compound between the layer and the solder and that has a maximum thickness that is less than approximately 1 μm.

Example 27: The electronic system of example 21 further comprising an intermetallic compound between the layer and the solder and that has a maximum thickness that is less than approximately 0.5 μm.

Example 28: The electronic system of example 21 further comprising a layer that comprises NiWP between the solder and a metal feature, wherein the solder comprises SnInCu.

Example 29: A device, apparatus, or system includes means to perform a method according to any one of the above implementations.

Example 30: At least one machine readable medium includes a plurality of

instructions that in response to being executed on a computing device, cause the computing device to perform a method according to any one of the above implementations.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

What is claimed is:

1. An electronic package, comprising:
a first die having at least one first interconnect with solder over or under a first metal feature; and
a second die having at least one second interconnect to the first die, the second interconnect comprising a second metal feature, the second interconnect comprising solder having indium and being over or under the second metal feature, the second interconnect including a layer between the solder and the second metal feature, wherein the layer comprises iron and has a different material than material of the first interconnect.

2. The electronic package of claim 1, wherein the layer further comprises cobalt.

3. The electronic package of claim 1, wherein the layer further comprises nickel.

4. The electronic package of claim 1, wherein the first interconnect is without an intermetallic compound (IMC) barrier layer between the solder and metal features on the first interconnect.

5. The electronic package of claim 1, wherein the first interconnect comprises a first layer between the solder and first metal feature, wherein the layer of the second interconnect is a second layer, and wherein the first layer is without iron.

6. The electronic package of claim 5, wherein the first layer comprises nickel and is a barrier layer.

7. The electronic package of claim 1, wherein the first interconnect comprises a first layer between the solder and first metal feature, wherein the layer of the second interconnect is a second layer, and wherein the first layer comprises iron and a first material and the second layer comprises iron and a second material different than the first material.

8. The electronic package of claim 7, wherein the first layer comprises iron and one of nickel and cobalt, and the second layer comprises iron and the other of nickel and cobalt.

9. The electronic package of claim 1, comprising multiple first interconnects and multiple second interconnects, and wherein the multiple first interconnects have a pitch greater than a pitch of the multiple second interconnects.

10. The electronic package of claim 1, wherein a thickness of the layer is approximately 1 micron or thicker.

11. The electronic package of claim 1, wherein the second die comprises an interconnect to a third die, wherein the second die is at least one of a bridge die, an embedded multi-die interconnect bridge (EMIB), or a chiplet, and wherein the second die couples the first die to the third die.

12. A method of manufacturing an electronic package comprising:
receiving a first die over a carrier;
forming a first interconnect on the first die and comprising placing solder over or under a first metal feature having copper;
forming a second interconnect on the first die and comprising forming a second metal feature comprising copper, solder over or under the second metal feature, and a layer between the solder and the second metal feature, wherein the layer comprises iron and has a different material than material of the first interconnect; and
coupling a second die to the first die through the second interconnect.

13. The method of claim 12, comprising coupling the second die to a third die over the carrier and having the first and second interconnects, and coupling through a second interconnect of the third die.

14. The method of claim 12, comprising forming multiple first interconnects on the first die with a pitch greater than 25 microns and multiple second interconnects on the first die with a pitch equal to or less than 25 microns.

15. The method of claim 12, wherein forming the second interconnect comprises covering an intermediate assembly with the first and second metal features with a resist; exposing the second metal features through openings in the resist without exposing the first metal features; and placing the layer on the second metal features within the openings.

16. An electronic system, comprising:
multiple first dice;
at least one first interconnect on each first die and comprising solder over or under a first metal feature;
at least one second interconnect on each first die and comprising a second metal feature, solder comprising indium, copper, and tin over or under the second metal feature, and a layer between the solder and the second metal feature, wherein the layer comprises one of: (1) nickel, (2) iron and cobalt, and (3) iron and nickel, and wherein the layer has a different material than material of the first interconnect; and
a second die coupled to the second interconnects of multiple first dice.

17. The electronic system of claim 16, wherein at least one of the first interconnects or at least one of the second interconnects or both has multiple layers comprising at least one layer over the solder and at least one layer under the solder, wherein the layer over the solder has a different material than a material of the layer under the solder.

18. The electronic system of claim 17, wherein both layers above and below the solder on a same interconnect comprises iron, and wherein the layer under the solder comprises a first additional material different than a second additional material of the layer over the solder.

19. The electronic system of claim 16, wherein the layer is a barrier layer, and the system comprises a Cu layer between the barrier layer and the solder.

20. The electronic system of claim 16, wherein the solder comprises nickel, tungsten, and phosphorous.
